(19) United States
(12) Patent Application Publication
(10) Pub. No.: US 2008/0316721 A1
(43) Pub. Date: Dec. 25, 2008

(54) ELECTRODE STRUCTURE BODY AND METHOD OF FORMING THE SAME, ELECTRONIC COMPONENT, AND MOUNTING SUBSTRATE

(75) Inventor: Keigo MAKI, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/112,481

(22) Filed: Apr. 30, 2008

(30) Foreign Application Priority Data
Jun. 19, 2007 (JP) 2007-161760

(51) Int. Cl. H05K 7/06; H01B 5/00; H01R 43/00

(52) U.S. Cl. 361/760; 174/126.2; 29/885

(57) ABSTRACT

An electrode structure body of the present invention is composed of a metal electrode, and a solder alloy layer (a tin/nickel alloy layer) formed on a surface of the metal electrode. The solder alloy layer is obtained by reflow-heating the solder layer formed on the metal electrode and then removing the solder layer. This electrode structure body can be applied to an external connection electrode of an electronic component or a mounting substrate.

### CROSS-REFERENCE TO RELATED APPLICATIONS

This application is based on and claims priority of Japanese Patent Application No. 2007-161760 filed on Jun. 19, 2007, the entire contents of which are incorporated herein by reference.

### BACKGROUND OF THE INVENTION

1. Field of the Invention

The present invention relates to an electrode structure body and a method of forming the same, an electronic component, and a mounting substrate and, more particularly, an electrode structure body and a method of forming the same, which are applicable to connection electrodes of an electronic component and a mounting substrate, and an electronic component and a mounting substrate having the same.

2. Description of the Related Art

In the prior art, as the package in which the semiconductor chip is mounted to constitute the semiconductor device, there is the BGA (Ball Grid Array) package. In the BGA package, the semiconductor chip is mounted on the wiring substrate (interposer) and the solder bumps are provided under the wiring substrate. As shown in FIG. 1, solder bumps 300 are formed by mounting a solder ball on electrode pads 200 provided on a wiring substrate 100 respectively or by screen-printing the solder.

As the technology related to the solder connection, in Patent Literature 1 (Patent Application Publication (KOKAI) 2002-158447), it is set forth that, when the conductor posts provided to connecting members are connected to lands of the connected members via the adhesive layer, the solder layer is formed on top end portions of conductor posts beforehand and then a heat treatment is applied to the solder layer prior to the solder connection, whereby the multi-layered wiring board is manufactured with high reliability of the interlayer connection.

Also, in Patent Literature 2 (Patent Application Publication (KOKAI) 2002-353593), it is set forth that openings in the insulating layer of the printed wiring board, in which mounting pads are arranged are formed by the laser, and then surfaces of the mounting pads are coated with the solder or plated with nickel or gold, or a silver or tin is deposited on the surfaces of the mounting pads by the chemical process, whereby a hindrance to the solder joining at a time of mounting is prevented.

As shown in FIG. 1, in the BGA package in the prior art, the solder bumps 300 whose height is 100 to 350 μm are used as the external connection terminal. Therefore, a thickness of the wiring substrate 100 is increased by a height of the solder bump. As a result, such a problem exists that this BGA package cannot readily respond to the package of which the thinner type is required.

Also, as shown in FIG. 2, when the solder is formed particularly by the screen printing, a variation in height of the solder bump 300 (about +30 μm) is caused by a variation in a supply quantity of the solder, or the like. Therefore, this BGA package cannot readily respond to the case where a high coplanarity is requested.

Further, as shown in FIG. 3, when the electrode pads 200 are aligned at a narrow pitch, in some cases the solder bumps 300 are connected mutually and an electrical short-circuit is generated, which acts as a factor of reduction of yields. In addition to this, in order to exclude portions of the wiring substrate on which the solder bumps 300 are formed defectively in a plurality of chip areas of the wiring substrate 100, the non-defective product must be sorted out by the visual inspection equipment after the solder bumps 300 are formed. As a result, such a problem exists that the man-hour is increased.

Besides, in order to prevent an occurrence of the defective in solder bumps 300 in FIG. 2 or FIG. 3, the strict management of the screen printing equipment used to form the solder bumps 300, the mask and the process condition used in this equipment, and the like is required. Therefore, the process becomes complicated and a reduction of the production efficiency is brought about.

### SUMMARY OF THE INVENTION

It is an object of the present invention to provide an electrode structure body which can respond to the thinner type and whose coplanarity can be set satisfactorily and which also can be formed by a simple method, and a method of forming the same, an electronic component, and a mounting substrate.

The present invention relates to an electrode structure body provided on a substrate, the electrode structure body is composed of a metal electrode, and a solder alloy layer formed on a surface of the metal electrode.

The electrode structure body of the present invention is composed of a metal electrode, and a solder alloy layer (a tin/nickel alloy layer, or the like) formed on a surface of the metal electrode. The bump is not provided onto a connection electrode.

In the present invention, the bump is omitted, and the connection electrodes having a good uniformity of height are utilized as the external connection portions. Therefore, this electrode structure body can set a coplanarity satisfactorily and also can reduce a thickness by a height of the bumps. Also, since a tin as a major component of the solder is left on the surface of the connection electrode, joining at the same level as the case where the solder bumps are utilized can be obtained.

The electrode structure body of the present invention is applicable to the external connection electrode of various electronic components, mounting substrates, and the like.

Also, the present invention is concerned with a method of forming an electrode structure body, which includes the steps of forming a metal electrode on an electronic component or a substrate; forming a solder layer on the metal electrode; forming a solder alloy layer between the metal electrode and the solder layer by reflow-heating the solder layer; and obtaining a connection electrode by removing the solder layer to expose the solder alloy layer.

The above-mentioned electrode structure body of the present invention can be easily formed by using the forming method of the present invention.

In the method of forming the electrode structure body of the present invention, even though respective heights of the solder bumps are varied, a coplanarity is decided by the connection electrodes whose heights are uniform because the solder bumps are removed. Therefore, a coplanarity can be set good.

Also, even though the electrical short-circuit between the solder bumps occurs when the metal electrodes are arranged at a narrow pitch, the solder bumps are removed in a state that the solder of the short-circuited portion is contained. Therefore, there is no possibility that the external connection electrodes are short-circuited.

Besides, since the solder bumps are formed so as to obtain the solder alloy layers, there is no need to consider occurrences of the variation in the height and the electrical short-circuit. Therefore, the strict process management in the step of forming the solder bumps is not needed. In addition to this, there is no need to sort out the non-defective product of the solder bumps by the visual inspection equipment which is introduced specially. As a result, the man-hour can be reduced considerably and a production efficiency and a manufacturing yield can be improved.

As described above, the electrode structure body of the present invention can respond easily to the thinner type and can set a coplanarity thereof satisfactorily and also can be formed by a simple method.

### BRIEF DESCRIPTION OF THE DRAWINGS

FIG. 1 is a sectional view (#1) showing the problem of the BGA package in the prior art;

FIG. 2 is a sectional view (#2) showing the problem of the BGA package in the prior art;

FIG. 3 is a sectional view (#3) showing the problem of the BGA package in the prior art;

FIGS. 4A to 4E are sectional views showing a first forming method of an electrode structure body according to an embodiment of the present invention;

FIGS. 5A to 5D are sectional views showing a second forming method of an electrode structure body according to an embodiment of the present invention;

FIGS. 6A to 6D are sectional views showing a third forming method of an electrode structure body according to an embodiment of the present invention;

FIG. 7 is a schematic view showing a sectional appearance of the external connection electrode of the electrode structure body according to an embodiment of the present invention;

FIG. 8 is a sectional view showing an example in which the electrode structure body according to the embodiment of the present invention is applied to the external connection electrode of a semiconductor device having a CSP structure;

FIGS. 9A and 9B are sectional views showing a state in which the semiconductor device in FIG. 8 is connected to the mounting substrate;

FIG. 10 is a sectional view showing an example in which the electrode structure body according to the embodiment of the present invention is applied to the external connection electrode of an interposer;

FIGS. 11A and 11B are sectional views showing a state in which the semiconductor device in FIG. 10 is connected to the mounting substrate;

FIGS. 12A and 12B are sectional views showing an example in which the electrode structure body according to the embodiment of the present invention is applied to the external connection electrode of a mounting substrate; and

FIG. 13 is a sectional view showing an example in which the electrode structure body according to the embodiment of the present invention is applied to the external connection electrode of a semiconductor chip.

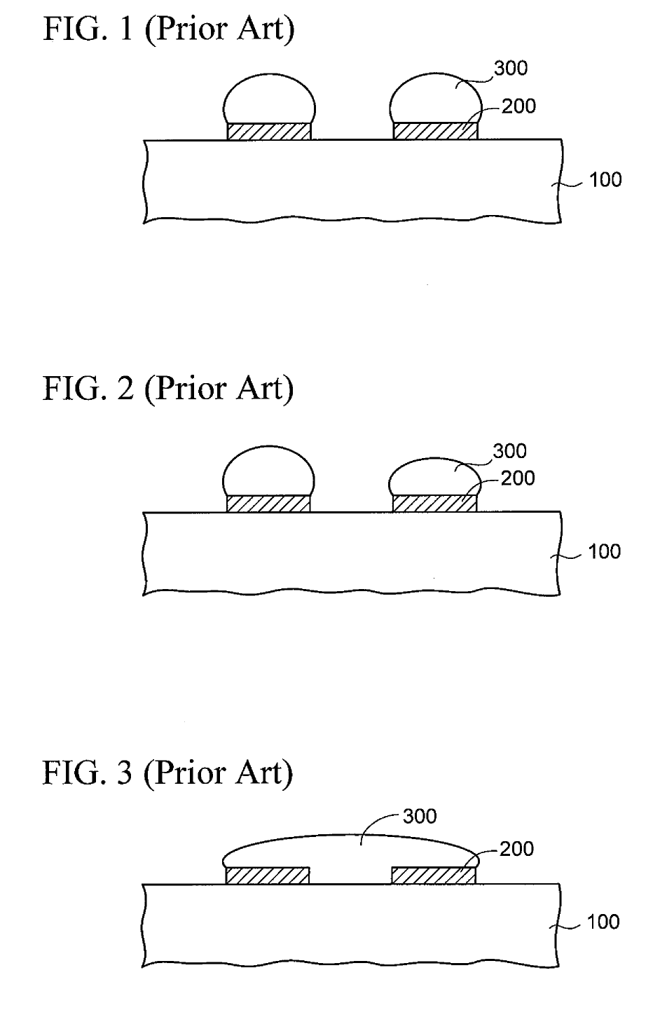

### DETAILED DESCRIPTION OF THE PREFERRED EMBODIMENTS

An embodiment of the present invention will be explained with reference to the accompanying drawings hereinafter.

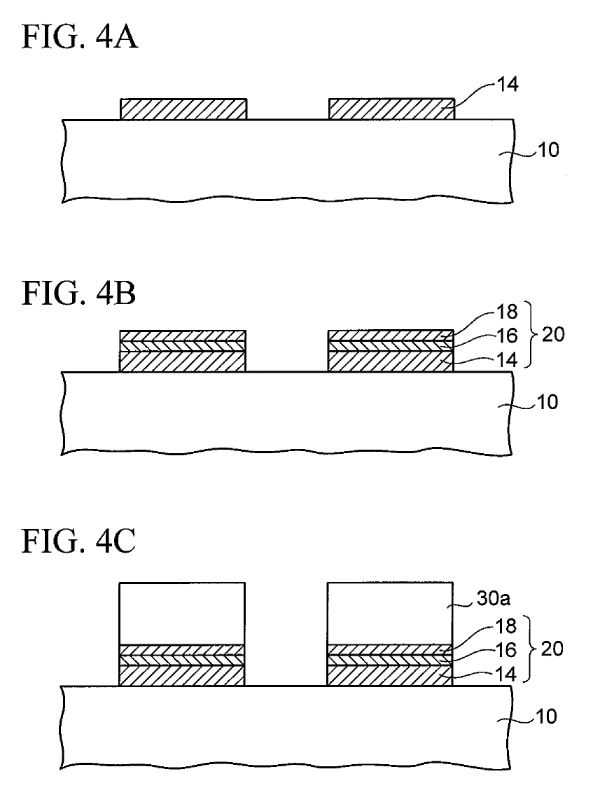

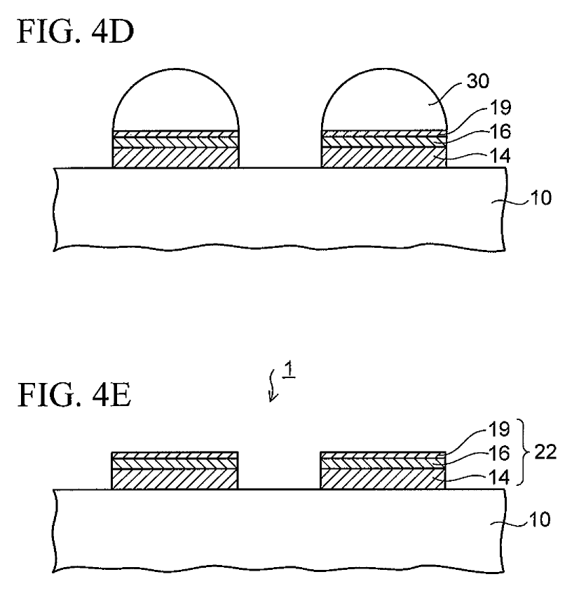

FIGS. 4A to 4E are sectional views showing a first forming method of an electrode structure body according to an embodiment of the present invention;

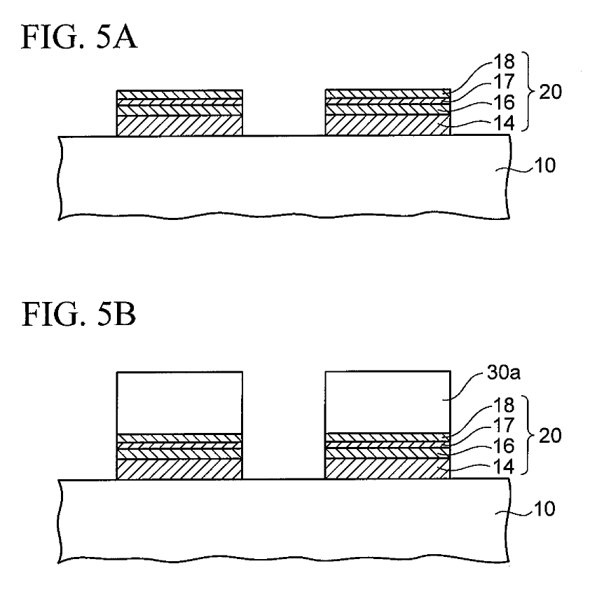

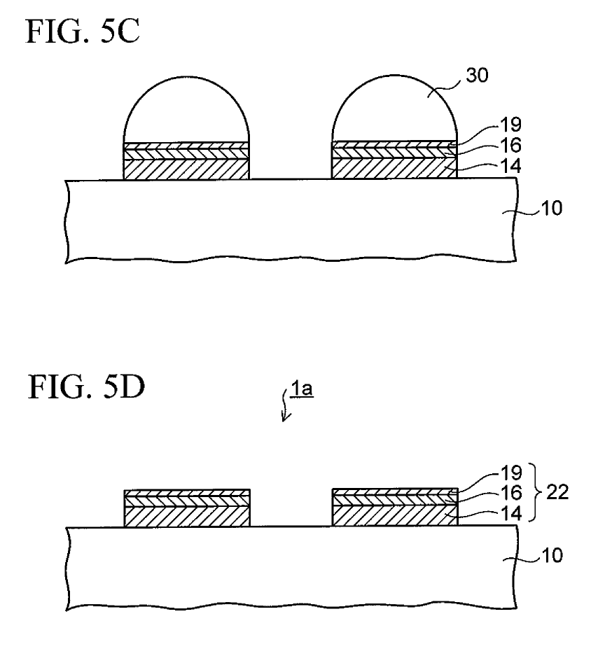

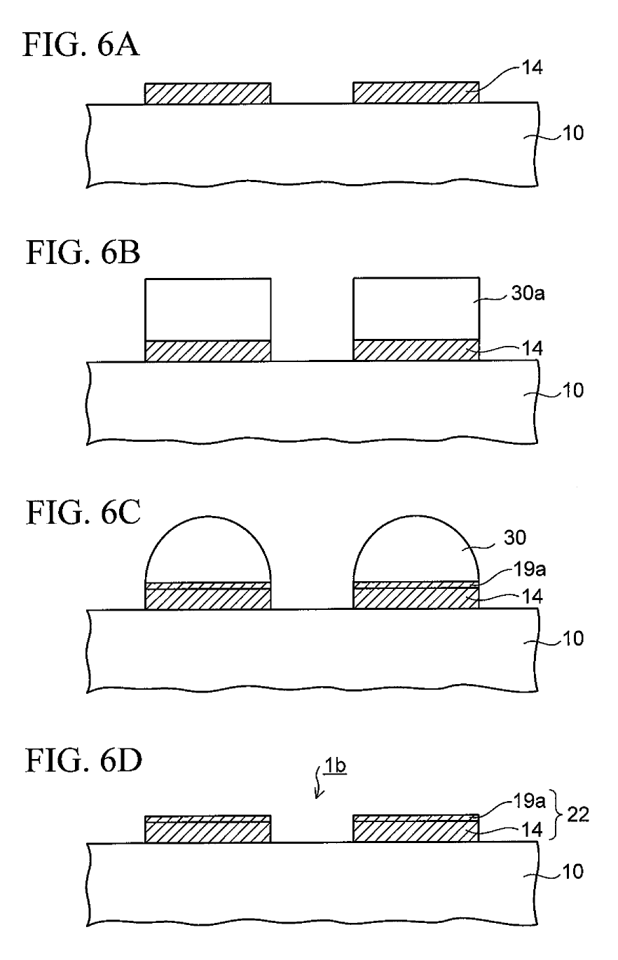

FIGS. 5A to 5D are sectional views showing a second forming method of the same electrode structure body, and FIGS. 6A to 6D are sectional views showing a third forming method of the same electrode structure body.

In the first forming method of the electrode structure body according to the present embodiment, as shown in FIG. 4A, first, copper (Cu) electrodes 14 (metal electrodes) acting as the connection electrodes are formed on a substrate 10. A multi-layered wiring (not shown) is provided in the substrate 10, and the Cu electrodes 14 are formed to be connected to the multi-layered wiring.

As described later, as the substrate 10 of the present embodiment on which the Cu electrodes 14 are provided, not only the substrate on which only the wirings are provided but also the wiring portions of various electronic components such as the interposer of the semiconductor device having the CSP (Chip Size Package) structure, and the like may be employed.

Then, as shown in FIG. 4B, a nickel (Ni) layer 16 is formed on the Cu electrodes 14, and then a gold (Au) layer 18 is formed thereon. The Ni layer 16 and the Au layer 18 are formed selectively on the Cu electrodes 14 by the electroless plating or the electroplating.

A film thickness of the Cu electrode 14 is set to 10 to 100 μm, a film thickness of the Ni layer 16 is set to about 3 μm, and a film thickness of the Au layer 18 is set to about 0.2 μm. The Ni layer 16 is provided to prevent a surface oxidation of the Cu electrode 14, and the Au layer 18 is provided to get an enough wetting of the solder layer formed thereon.

As a result, metal electrodes 20 constructed by forming the Cu electrode 14, the Ni layer 16, and the Au layer 18 in order from the bottom are obtained.

Then, as shown in FIG. 4C, a solder layer 30a is formed on the metal electrodes 20 by printing the solder paste by means of the screen printing. As the solder layer 30a, various solders containing a tin can be employed. As a preferred example of the solder layer 30a, a lead (Pd)-free tin/silver/copper (Sn/Ag/Cu) solder is employed.

Then, the solder layer 30a is reflow-heated at a temperature of about 250° C. Thus, as shown in FIG. 4D, the solder layer 30a is cured and solder bumps 30 having a height of 100 to 350 μm are obtained. At this time, Sn as a major component of the solder layer 30a and Ni of the Ni layer 16 are alloyed, and an SnNi alloy layer 19 is formed between the Ni layer 16 and the solder bump 30. Most of the Au layer 18 between the Ni layer 16 and the solder layer 30a is diffused into the solder bump 30 by the reflow heating, and the Au layer 18 substantially disappears.

Then, as shown in FIG. 4E, the SnNi alloy layers 19 are exposed by etching the solder bumps 30 by using the etchant (Enstrip TL: manufactured by Meltex Corporation). Thus, external connection electrodes 22 each composed of the Cu electrode 14, the Ni layer 16, and the SnNi alloy layer 19 are obtained. Then, the uppermost SnNi alloy layer 19 of the external connection electrode 22 acts as the joining surface. The external connection electrode 22 obtained by the first forming method is constructed by forming the SnNi alloy layer 19 (the solder alloy layer) on the Cu electrode 14 and the Ni layer 16 (the metal electrode).

Accordingly, a first electrode structure body 1 according to the present embodiment is obtained.

Unlike the present embodiment, when the solder bumps 30 are utilized as the external connection electrodes, various disadvantages are caused such that a thickness of the wiring substrate is increased, the electrical short-circuit between the solder bumps 30 occurs, a coplanarity worsens because respective heights of the solder bumps 30 are varied, and the like.

However, in the present embodiment, the SnNi alloy layers 19 are utilized as the external connection electrodes by removing the solder bumps 30. Therefore, a thickness of the wiring substrate can be thinned by a thickness corresponding to the height of the solder bump 30, and this structure can respond to the thinner type. Also, even though the electrical short-circuit between the solder bumps 30 occurs when the metal electrodes 20 in FIG. 4B are arranged at a narrow pitch, the solder bumps 30 are removed in a state that the solder of the short-circuited portion is contained. Therefore, there is no possibility that the external connection electrodes 22 are short-circuited.

Further, even when respective heights of the solder bumps 30 are varied, a coplanarity is decided by the external connection electrodes 22 whose heights are uniform because the solder bumps 30 are removed. Therefore, a coplanarity can be set good.

Besides, since the solder bumps 30 are formed so as to obtain the SnNi alloy layers 19, there is no need to consider occurrences of the variation in the height thereof and the electrical short-circuit between them. Therefore, the strict process management in the step of forming the solder bumps 30 is not needed. In addition to this, there is no need to sort out the non-defective product of the solder bumps 30 by the visual inspection equipment. As a result, the man-hour can be reduced considerably and a production efficiency and a manufacturing yield can be improved.

Also, the steps of forming the solder alloy layer in the present embodiment (from the step of forming the solder layer 30a to the step of reflow-heating) is the same as the general solder bump forming step. Therefore, there is no need to introduce particularly the expensive manufacturing equipment.

Also, in the second forming method of the electrode structure body according to the present embodiment, as shown in FIG. 5A, first, a palladium (Pd) layer 17 is formed between the Ni layer 16 and the Au layer 18 in the structure body in FIG. 4B in the first forming method. Accordingly, the metal electrode 20 is constructed by forming the Cu electrode 14, the Ni layer 16, Pd layer 17 and the Au layer 18 in order from the bottom. In the case of this mode, a film thickness of the Ni layer 16 is set to 3 μm, a film thickness of the Pd layer 17 is set to 0.12 μm, and a film thickness of the Au layer 18 is set to 0.01 μm.

Then, as shown in FIG. 5B, the solder layer 30a is formed on the metal electrodes 20 by the similar method to the first forming method. Then, as shown in FIG. 5C, like the first forming method, the solder bumps 30 are obtained by reflow-heating the solder layer 30a to cure it. At this time, Sn of the solder layer 30a and Ni of the Ni layer 16 are alloyed and thus the SnNi alloy layer 19 is formed between the Ni layer 16 and the solder bump 30. In the second forming method, the Au layer 18 and the Pd layer 17 are diffused into the solder bumps 30 in reflow-heating the solder layer 30a and substantially disappear.

Then, as shown in FIG. 5D, like the first forming method, the SnNi alloy layers 19 are exposed by removing the solder bumps 30 by means of the etching. Thus, the external connection electrodes 22 each composed of the Cu electrode 14, the Ni layer 16, and the SnNi alloy layer 19 are obtained. Then, the uppermost SnNi alloy layer 19 of the external connection electrode 22 serves as the joining surface.

With the above, a second electrode structure body 1a of the present embodiment can be obtained. In the second forming method, the external connection electrodes 22 having the same structure as those in the foregoing first electrode structure body 1 are obtained. In this event, by providing the Pd layer 17 between the Ni layer 16 and the Au layer 18, the SnNi alloy layer 19 which has a uniform film thickness and is dense rather than the case where the Pd layer 17 is not provided can be formed with good reliability.

Also, in the third forming method of the electrode structure body according to the present embodiment, as shown in FIG. 6A, the Ni layer 16 and the Au layer 18 formed in FIG. 4B in the first forming method are omitted in case that a surface oxidation of the Cu electrode 14 and a wetting of the solder do not become a problem. Then, as shown in FIG. 6B, the solder layer 30a is formed directly on the Cu electrodes 14 (the metal electrodes).

Then, as shown in FIG. 6C, the solder bumps 30 are obtained by reflow-heating the solder layer 30a to cure it. At this time, Sn of the solder bump 30 and Cu of the Cu electrode 14 are alloyed and thus an SnCu alloy layer 19a is formed between the Cu electrode 14 and the solder bump 30. Then, as shown in FIG. 6D, the SnCu alloy layers 19a are exposed by removing the solder bumps 30. Accordingly, the external connection electrodes 22 each composed of the Cu electrode 14 and the SnCu alloy layer 19a are obtained.

With the above, a third electrode structure body 1b of the present embodiment can be obtained.

In the present embodiment, a mode in which the SnNi alloy layer 19 or the SnCu alloy layer 19a is formed as the uppermost layer of the external connection electrode 22 is illustrated. In this case, the alloy layer may be formed between the metal other than Ni and Cu and the solder. That is, the external connection electrode of the electrode structure body of the present embodiment may be constructed by providing the alloy layer of that metal and the solder on the single layer or stacked-layered metal electrode, and the metal electrode made of any of various metal materials can be used.

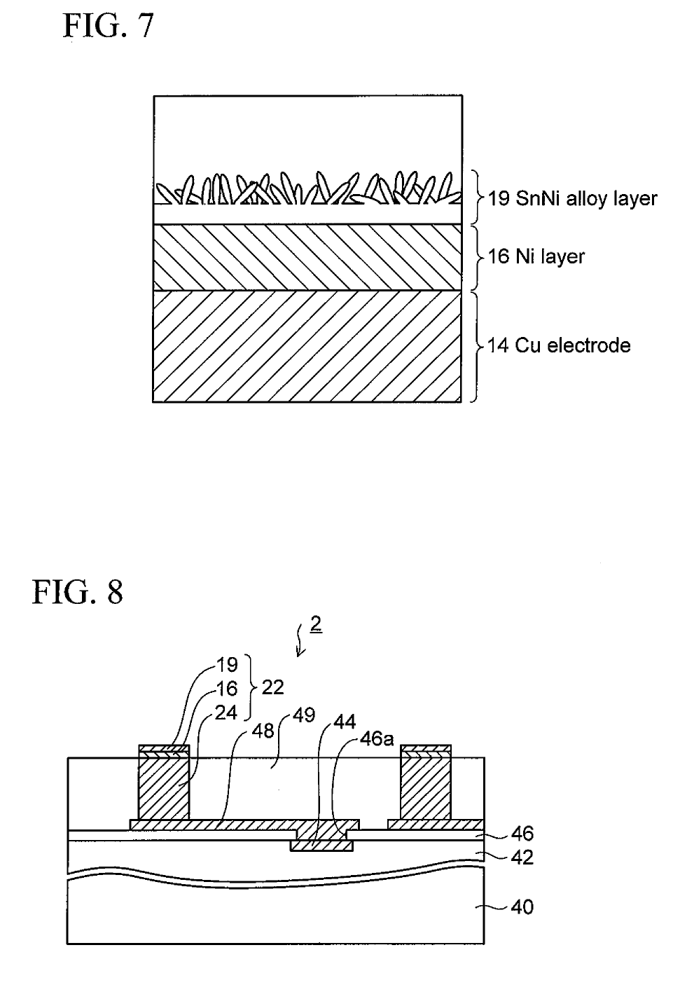

The inventor of this application formed actually the external connection electrode 22 of the electrode structure body by the above first forming method, then took a picture of a section of the external connection electrode 22 with the SEM after the solder bump 30 was removed, and then made the analysis of metallic elements in the alloy layer. In FIG. 7, a schematic view depicted based on the SEM image is shown.

According to this result, as shown in FIG. 7, it was checked that the SnNi alloy layer 19 is formed on the Ni layer 16 on the Cu electrode 14. The SnNi alloy layer 19 was formed such that fine needle-like crystals were directed in random directions, and its upper surface side was formed in a rough surface state. A film thickness of the SnNi alloy layer 19 containing top ends of the needle-like crystals directed upward from the boundary to the Ni layer 16 was about 2 μm.

In the present embodiment, the external connection electrode 22 can be thinned rather than the case where the solder bump 30 (FIG. 4D) whose height is more than 100 μm is left. Also, since a major component (Sn) of the solder is left on the surface of the external connection electrode 22, joining at the same level as the case where the solder bumps 30 are utilized can be obtained.

The electrode structure body of the present embodiment can be applied to the connection electrodes of various electronic components and the mounting substrate. That is, the electrode structure body of the present embodiment is connected to the wiring portions of the electronic component or the mounting substrate. Examples will be explained hereunder.

In FIG. 8, an example in which the electrode structure body according to the present embodiment is applied to the external connection electrode of the first semiconductor device (the electronic component) having the CSP structure is shown. The CSP is manufactured by such a manufacturing process that the film formation, the processing, etc. concerning the CSP structure are carried out in a silicon wafer state, and then individual CSPs are obtained by dicing the silicon wafer.

As shown in FIG. 8, in a first semiconductor device 2, the multi-layered wiring (not shown) connected to semiconductor circuits (not shown) is formed on a silicon substrate 40 on which the semiconductor circuits are formed, and also internal electrodes 44 connected to the multi-layered wiring are formed on an insulating layer 42. Then, a passivation film 46 in which opening portions 46a are formed on the internal electrodes 44 and which is made of polyimide, or the like is formed on the insulating layer 42. Also, re-wiring layers 48 connected to the internal electrodes 44 are formed on the passivation film 46, and pitches and arrangements of the internal electrodes 44 are converted into a predetermined layout by the re-wiring layers 48.

Also, Cu electrodes 24 (Cu posts) are provided upright to the connection portions of the re-wiring layers 48. The Cu electrodes 24 are embedded in a sealing resin 49.

The Ni layer 16 is formed on the Cu electrodes 24, and the SnNi alloy layer 19 obtained by the above forming method is formed thereon. The external connection electrode 22 of the second semiconductor device 2 is composed of the Cu electrode 24, the Ni layer 16, and the SnNi alloy layer 19.

In the first semiconductor device 2, the external connection electrodes 22 are obtained by preparing the silicon wafer on which the Cu electrodes 24 (metal electrodes) connected to the wirings are provided in a plurality of chip areas, and then forming the solder alloy layer on the surfaces of the Cu electrodes 24 before or after the silicon wafer is cut.

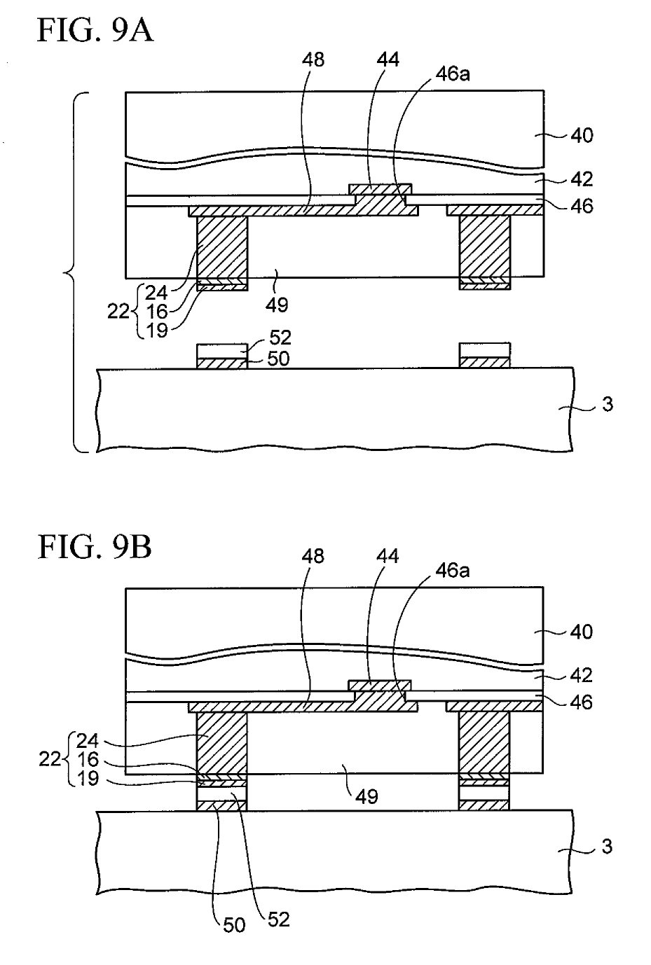

Next, a method of mounting the first semiconductor device 2 equipped with the external connection electrodes 22 having such structure on the mounting substrate (mother board) will be explained hereunder. As shown in FIG. 9A, first, a solder layer 52 is formed on electrode pads 50 of a mounting substrate 3. Then, the external connection electrodes 22 of the first semiconductor device 2 are arranged the solder layers 52 on the mounting substrate 3, and then reflow-heated. Accordingly, as shown in FIG. 9B, the external connection electrodes 22 of the first semiconductor device 2 are connected to the electrode pads 50 of the mounting substrate 3 via the solder layer 52.

At this time, the joining surface of the external connection electrode 22 of the first semiconductor device 2 is made of the SnNi alloy layer 19 containing Sn as a major component of the solder. Therefore, since a sufficient wetting of the solder layer 52 can be ensured, the external connection electrode 22 can be joined to the solder layer 52 with good reliability. Also, since a coplanarity of the external connection electrode 22 can be set good, yield in mounting the first semiconductor device 2 on the mounting substrate 3 can be improved. Also, a thickness of the electronic device, which is constructed by mounting the semiconductor device 2 on the mounting substrate 3, can be reduced because the solder bump of the semiconductor device 2 is omitted, and thus this electronic device can respond to the thinner type.

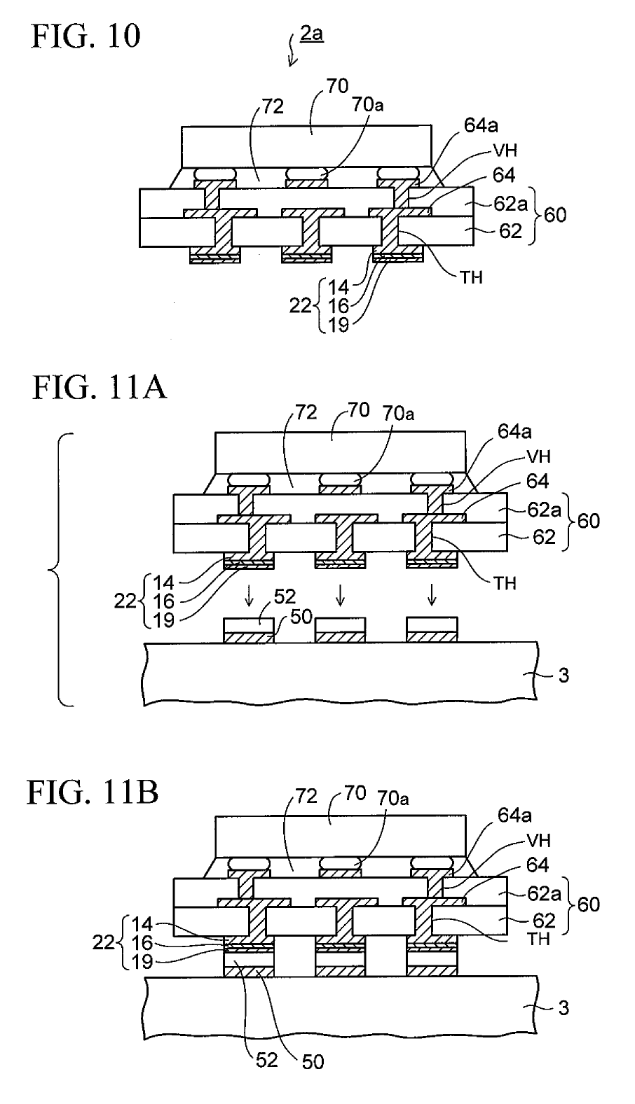

Also, in FIG. 10, an example in which the electrode structure body according to the present embodiment is applied to the external connection electrode of the second semiconductor device (electronic component) that is constructed by mounting the semiconductor chip on the interposer is shown.

As shown in FIG. 10, in an interposer 60 (a wiring substrate) of a second semiconductor device 2a, first wiring layers 64 are formed on an upper surface of a first insulating layer 62, and the first wiring layers 64 are connected to the external connection electrodes 22 provided on the under surface of the first insulating layer 62 via through holes TH provided in the first insulating layer 62. Then, a second insulating layer 62a is formed on the first wiring layers 64, and via holes VH reaching the first wiring layers 64 respectively are provided in the second insulating layer 62a.

Also, second wiring layers 64a connected to the first wiring layers 64 via the via holes VH are formed on the second insulating layer 62a.

Also, bumps 70a of a semiconductor chip 70 are flip-chip connected to connection portions of the second wiring layers 64a. Also, an underfill resin 72 is filled into a clearance under the semiconductor chip 70.

Then, the external connection electrodes 22 provided on the lower surface of the interposer 60 of the second semiconductor device 2a are constructed by forming the SnNi alloy layer 19 obtained by the above forming method on (in FIG. 10, under) the Cu electrodes 14 and the Ni layers 16.

In the second semiconductor device 2a, the external connection electrodes 22 are obtained by preparing the interposer 60 on which the Cu electrodes 14 (the metal electrodes) are provided, and then forming the solder alloy layer on the surfaces of the Cu electrodes 14 before or after the semiconductor chip 70 is mounted.

In this case, the second semiconductor device 2a may be constructed by mounting a plurality of semiconductor chips on the interposer 60.

Next, a method of mounting the second semiconductor device 2a equipped with the external connection electrodes 22 having such structure on the mounting substrate will be explained hereunder. As shown in FIG. 11A, first, the solder layer 52 is formed on the electrode pads 50 of the mounting substrate 3 (the mother board). Then, the external connection electrodes 22 of the second semiconductor device 2a in FIG. 10 are arranged on the solder layers 52 on the mounting substrate 3, and reflow-heated. Thus, as shown in FIG. 11B, the external connection electrodes 22 of the second semiconductor device 2a are connected to the electrode pads 50 of the mounting substrate 3 via the solder layers 52. Also in case the second semiconductor device 2a is mounted, the advantages similar to those in the case where the above first semiconductor device 2 is mounted can be achieved.

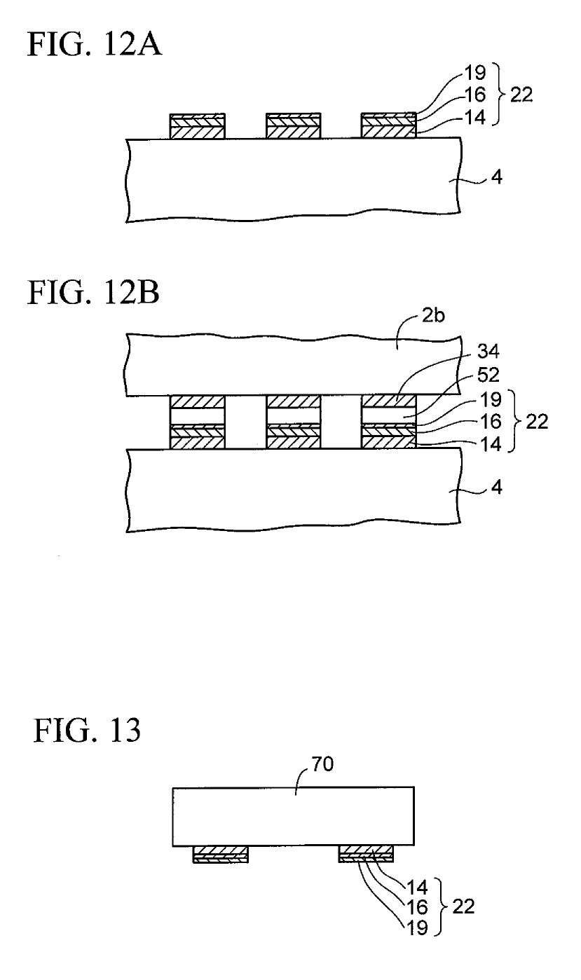

Also, in FIG. 12A, an example in which the electrode structure body according to the present embodiment is applied to the external connection electrode of the mounting substrate (the mother board) on which the mounted body (the semiconductor device, or the like) is mounted is shown. As shown in FIG. 12A, the external connection electrodes 22 connected to the wiring portions (not shown) are provided on a mounting substrate 4. The external connection electrode 22 is constructed by forming the SnNi alloy layer 19 obtained by the above forming method on the Cu electrode 14 and the Ni layer 16. Also in the case of this mode, the external connection electrodes 22 are obtained by preparing the mounting substrate 4 on which the Cu electrodes 14 connected to the wirings are provided, and then forming the solder alloy layer on the surfaces of the Cu electrodes 14.

Then, as shown in FIG. 12B, the solder layer 52 is formed on electrode pads 34 of a third semiconductor device 2b, and then the electrode pads 34 of the third semiconductor device 2b are connected to the external connection electrodes 22 of the mounting substrate 4 via the solder layers 52. In this mode, since the solder bumps are not provided to the electrode pads 34 of the third semiconductor device 2b as the mounted body, the advantages similar to those in the case where the above first semiconductor device 2 is mounted can be achieved.

Also, as shown in FIG. 13, the electrode structure body according to the present embodiment may be applied to the external connection electrodes of the semiconductor chip 70 (the electronic component). The external connection electrodes 22 are constructed by forming the SnNi alloy layer 19 obtained by the above forming method on (in FIG. 13, under) the Cu electrodes 14 and the Ni layers 16. In the case of this mode, the external connection electrodes 22 are obtained by preparing the semiconductor chip (or the silicon wafer prior to the cutting) on which the Cu electrodes 14 (the metal electrodes) are provided, and then forming the solder alloy layer on the surfaces of the Cu electrodes 14.

Similarly, the external connection electrodes 22 of the semiconductor chip 70 are flip-chip mounted on the wiring substrate (not shown) such as the interposer, or the like via the solder layer. In this mode, since the solder bumps are not provided to the external connection electrodes 22 of the semiconductor chip 70, the advantages similar to those in the case where the above first semiconductor device 2 is mounted can be achieved.

The mode in which the electrode structure body according to the present embodiment is applied to the external connection electrodes of the electronic component or the mounting substrate is shown. However, the electrode structure body according to the present embodiment can be applied to the external connection electrodes of various electronic devices that has the external connection electrodes and are connected to other device via the solder layer. Also, the SnNi alloy layer 19 is illustrated as the solder alloy layer of the external connection electrode 22. However, various solder alloy layers such as the SnCu alloy layer, and the like may be formed.

What is claimed is:

1. An electrode structure body provided on a substrate, wherein the electrode structure body is composed of a metal electrode, and a solder alloy layer formed on a surface of the metal electrode.

2. An electrode structure body according to claim 1, wherein the metal electrode is constructed by forming a nickel layer on a copper electrode, and the solder alloy layer is formed of a tin/nickel alloy layer.

3. An electrode structure body according to claim 1, wherein the metal electrode is formed of a copper electrode, and the solder alloy layer is formed of a tin/copper alloy layer.

4. A method of forming an electrode structure body, comprising the steps of:
forming a metal electrode on an electronic component or a substrate;
forming a solder layer on the metal electrode;
forming a solder alloy layer between the metal electrode and the solder layer by reflow-heating the solder layer; and
obtaining a connection electrode by removing the solder layer to expose the solder alloy layer.

5. A method of forming an electrode structure body, according to claim 4, wherein the step of forming the metal electrode includes a step of forming a nickel layer and a gold layer in order on a copper electrode, and
the step of forming the solder alloy layer is a step of forming a tin/nickel alloy layer.

6. A method of forming an electrode structure body, according to claim 4, wherein the step of forming the metal electrode includes a step of forming a nickel layer, a palladium layer, and a gold layer in order on a copper electrode, and
the step of forming the solder alloy layer is a step of forming a tin/nickel alloy layer.

7. A method of forming an electrode structure body, according to claim 4, wherein the step of forming the metal electrode includes a step of forming a copper electrode, and
the step of forming the solder alloy layer is a step of forming a tin/copper alloy layer.

8. An electronic component including connection electrode,
wherein the connection electrode is composed of a metal electrode, and a solder alloy layer formed on a surface of the metal electrode.

9. A mounting substrate on which a mounted body is mounted and including connection electrode,
wherein the connection electrode is composed of a metal electrode, and a solder alloy layer formed on a surface of the metal electrode.
